(19) United States
(12) Patent Application Publication
(10) Pub. No.: US 2014/0024217 A1
(43) Pub. Date: Jan. 23, 2014

(54) METHOD FOR FORMING RESIST PATTERNS AND METHOD FOR PRODUCING PATTEREND SUBSTRATES EMPLOYING THE RESIST PATTERNS

(71) Applicant: FUJIFILM Corporation, Tokyo (JP)

(72) Inventors: Akihiko OHTSU, Haibara-gun (JP); Katsuhiro NISHIMAKI, Haibara-gun (JP)

(73) Assignee: FUJIFILM Corporation, Tokyo (JP)

(21) Appl. No.: 14/039,249

(22) Filed: Sep. 27, 2013

Related U.S. Application Data
(63) Continuation of application No. PCT/JP2012/059290, filed on Mar. 29, 2012.

(30) Foreign Application Priority Data
Mar. 29, 2011 (JP) 2011-071406

(51) Int. Cl. H01L 21/3065

(52) U.S. Cl. CPC H01L 21/3065
USPC 438/694

(57) ABSTRACT

Residual film etching steps for etching a resist film, onto which a pattern of protrusions and recesses has been formed, include: a first etching step employing a first etching gas including a sedimentary gas that generates sediment during etching, to etch the resist film such that the sediment is deposited on the sidewalls of protrusions of a resist pattern while residual film is etched. In the steps following the first etching step, the resist film is etched such that the widths of the protrusions including the deposited sediment become a desired width greater than or equal to the widths of the protrusions prior to residual film etching. Thereby, it becomes possible for the widths of protrusions of resist patterns following residual film etching to become desired widths greater than or equal to the widths of the protrusions of the resist patterns prior to residual film etching when forming resist patterns.

### TECHNICAL FIELD

The present invention is related to a method for forming resist patterns employing molds having predetermined patterns of protrusions and recesses on the surfaces thereof and a method for producing patterned substrates employing the resist patterns.

### BACKGROUND ART

There are high expectations regarding utilization of pattern transfer techniques that employ a nanoimprinting method to transfer patterns onto resist coated on objects to be processed, in applications to produce magnetic recording media such as DTM (Discrete Track Media) and BPM (Bit Patterned Media) and semiconductor devices.

The nanoimprinting method is a development of the well known embossing technique employed to produce optical discs. In the nanoimprinting method, a mold (commonly referred to as a mold, a stamper, or a template), on which a pattern of protrusions and recesses is formed, is pressed against resist coated on a substrate, which is an object to be processed. Pressing of the original onto the resist causes the resist to mechanically deform or to flow, to precisely transfer the fine pattern. If a mold is produced once, nano level fine structures can be repeatedly molded in a simple manner. Therefore, the nanoimprinting method is an economical transfer technique that produces very little harmful waste and discharge. Therefore, there are high expectations with regard to application of the nanoimprinting method in various fields.

It is known that there are cases in which thin films of resist (residual film) that could not be removed by the protrusions of patterns of protrusions and recesses of molds remain in the recesses of resist patterns formed in resist films by nanoimprinting. It is also known that such residual film affects an etching step for etching substrates on which the resist films are formed.

Therefore, the step of etching substrates is generally executed after removing the residual film, as disclosed in U.S. Pat. No. 7,214,624.

### DISCLOSURE OF THE INVENTION

It is known that the side walls of the protrusions of resist patterns are also etched (by so called “side etching”) when residual film is removed by etching. In the case that the residual film is etched by plasma etching that employs oxygen gas or a noble gas as in U.S. Pat. No. 7,214,624, the influence of side etching becomes more significant as the resist pattern becomes finer. Therefore, there is a possibility that the protrusions of the resist pattern may become damaged and discontinuous. In such cases, a desired pattern cannot be formed in a substrate in the step of etching the substrate, which is the backing layer of the resist pattern, and processing accuracy deteriorates. Even if the protrusions are not damaged to the point that they become discontinuous when the residual film is etched, that the widths of the protrusions will decrease due to side etching is unavoidable. In such cases, the protrusions which are to function as masks may become discontinuous or collapse due to side etching during the step of etching the substrate, resulting in a desired pattern not being formed on the substrate and deterioration in processing accuracy.

In order to solve the aforementioned problem, it is necessary for the widths of the protrusions of the resist pattern when the residual film etching step is complete to be equal to the widths of the protrusions of the resist pattern prior to the residual etching step, or a desired value wider than the widths of the protrusions of the resist pattern prior to the residual etching step, taking side etching that will occur during the step of etching the backing substrate into consideration.

The present invention has been developed in view of the foregoing circumstances. It is an object of the present invention to provide a method for forming a resist pattern that enables the widths of protrusions of a resist pattern after residual film etching steps to be a desired value greater than or equal to the widths of the protrusions of the resist pattern prior to the residual film etching step.

It is another object of the present invention to provide a method for producing a substrate by etching using a resist pattern as a mask, that enables the processing accuracy of a pattern of protrusions and recesses corresponding to the resist pattern to be improved.

A resist pattern forming method of the present invention that achieves the above objective comprises:

pressing a fine pattern of protrusions and recesses of a mold having the fine pattern of protrusions and recesses on the surface thereof against a resist film on a substrate;

separating the mold from the resist film, and transferring the pattern of protrusions and recesses onto the resist film; and

executing residual film etching steps to etch the resist film to remove residual film of the resist film, onto which the pattern of protrusions and recesses has been transferred, by a reactive ion etching method; and is characterized by:

the residual film etching steps including: a first etching step that employs a first etching gas including a sedimentary gas that generates sediment during etching to etch the resist film under conditions such that the sediment is deposited on the side walls of protrusions of a resist pattern, which is the pattern of protrusions and recesses transferred onto the resist film, while the residual film is etched; and steps following the first etching step that etch the resist film such that the widths of the protrusions including the deposited sediment become a desired width greater than or equal to the widths of the protrusions prior to the residual film etching step.

In the present specification, the expression “sediment is deposited” on the side walls of protrusions of a resist pattern, which is the pattern of protrusions of a resist pattern refers to a state in which the sediment is merely deposited onto the side walls, and also to a state in which the ability of the sediment to bond to the side walls is greater than the ability of the sediment deposited on the side walls to be etched, resulting in the sediment being deposited onto the side walls.

The expression “the residual film is etched” refers to a state in which the ability of the sediment to bond to the bottoms of the recesses of the resist pattern is smaller than the ability of the sediment deposited on the bottoms to be etched, resulting in the sediment not being deposited on the bottoms and the residual film being progressively etched.

The residual film etching steps include “steps following the first etching step that etch the resist film such that the widths of the protrusions including the deposited sediment become a desired width greater than or equal to the widths of the protrusions prior to the residual film etching step”. This means that the residual etching steps are steps that etch the resist film such that the widths of the protrusions including the deposited sediment become the desired width greater than or equal to the widths of the protrusions prior to the residual film etching step by the first etching step. Alternatively, this means that the resist film is etched by further etching steps following the first etching step such that the widths of the protrusions including the deposited sediment become the desired width greater than or equal to the widths of the protrusions prior to the residual film etching step.

The “desired value” is a width of the protrusions necessary when the backing layer substrate is etched using the resist film in which the resist pattern is formed as a mask. The width refers to the width of the protrusions including the deposited sediment.

In the resist pattern forming method of the present invention, it is preferable for the sedimentary gas to be a fluorocarbon gas represented by CHₓF₄₋ₓ, wherein x is an integer within a range from 0 to 3.

In the resist pattern forming method of the present invention, it is preferable for the sedimentary gas to be at least one of CF₄, CHF₃ and CH₂F₂.

In the resist pattern forming method of the present invention, it is preferable for the percentage of the sedimentary gas in the first etching gas to be within a range from 5% to 50%.

In the resist pattern forming method of the present invention, it is preferable for the first etching gas to include oxygen gas. In this case, it is preferable for the ratio of the oxygen gas with respect to the sedimentary gas within the first etching gas being within a range from 0.01 to 5.

In the resist pattern forming method of the present invention, it is preferable for the first etching gas to include a noble gas. In this case, it is preferable for the ratio of the noble gas with respect to the sedimentary gas within the first etching gas to be within a range from 0.8 to 10.

In the resist pattern forming method of the present invention, it is preferable for etching during the first etching step to be executed under conditions such that the widths of the protrusions including the deposited sediment become greater than the desired value; and for the residual film etching steps to include a second etching step that etches the sediment deposited on the side walls of the protrusions such that the widths of the protrusions including the deposited sediment become the desired value, after the first etching step.

In the resist pattern forming method of the present invention, it is preferable for the percentage of the sedimentary gas in the first etching gas to be greater than the percentage of sedimentary gas in a second etching gas, which is utilized during the second etching step.

In the resist pattern forming method of the present invention, it is preferable for the percentage of oxygen gas in the first etching gas to be less than the percentage of oxygen gas in a second etching gas, which is utilized during the second etching step.

In the resist pattern forming method of the present invention, it is preferable for the reactive ion etching method to be an etching method that employs one of inductive coupling, capacitive coupling, and electron cyclotron resonance as a plasma generating technique.

In the resist pattern forming method of the present invention, it is preferable for the substrate to have at least one mask layer on the surface on which the resist film is formed.

In the resist pattern forming method of the present invention, it is preferable for the at least one mask layer to include at least one layer that includes chrome and/or chrome oxide.

Further, a method for producing patterned substrates of the present invention is characterized by comprising:

forming a resist pattern on a resist film by a resist pattern forming method as defined in any one of claims 1 through 14; and

etching the substrate using the resist film as a mask, to form a pattern of protrusions and recesses corresponding to the resist pattern on the surface of the substrate.

The resist pattern forming method of the present invention is characterized by the residual film etching steps including the first etching step that employs a first etching gas including a sedimentary gas that generates sediment during etching to etch the resist film under conditions such that the sediment is deposited on the side walls of protrusions of a resist pattern, which is the pattern of protrusions and recesses transferred onto the resist film, while the residual film is etched. As a result, it becomes possible for the widths of the protrusions including the deposited sediment to become a desired width greater than or equal to the widths of the protrusions prior to the residual film etching steps. This is considered to be because the sediment being deposited onto the side walls suppresses the resist portions of the protrusions of the resist pattern being etched, and the sediment itself compensates for etched resist portions of the protrusions.

In addition, the method for forming a patterned substrate of the present invention is characterized by forming a resist pattern on a resist film by the resist pattern formation method described above, and by etching a substrate using the resist film as a mask, to form a pattern of protrusions and recesses corresponding to the resist pattern on the surface of the substrate. Therefore, etching using a resist pattern having protrusions with widths of a desired value greater than or equal to the widths of the protrusions prior to the residual film etching step as a mask becomes possible. As a result, the accuracy in producing a pattern of protrusions and recesses corresponding to the resist pattern can be improved in the production of the patterned substrate.

### BRIEF DESCRIPTION OF THE DRAWINGS

FIG. 1A is a schematic sectional view that illustrates a mold employed in a resist pattern forming method according to an embodiment of the present invention.

FIG. 1B is a schematic magnified view that illustrates the cross section of a portion of a patterned region of the mold of FIG. 1A.

FIG. 2A is a schematic sectional view that illustrates a step of the resist pattern forming method according to the embodiment of the present invention.

FIG. 2B is a schematic sectional view that illustrates a step of the resist pattern forming method according to the embodiment of the present invention.

FIG. 2C is a schematic sectional view that illustrates a step of the resist pattern forming method according to the embodiment of the present invention.

FIG. 3A is a schematic sectional view that illustrates the state of a resist pattern following a first etching step and prior to a second etching step in the resist pattern forming method.

FIG. 3B is a schematic sectional view that illustrates the state of the resist pattern following the second etching step in the resist pattern forming method.

FIG. 4A is a schematic sectional view that illustrates a step of a method for producing a patterned substrate according to an embodiment of the present invention.

FIG. 4B is a schematic sectional view that illustrates a step of the method for producing a patterned substrate according to the embodiment of the present invention.

FIG. 4C is a schematic sectional view that illustrates a step of the method for producing a patterned substrate according to the embodiment of the present invention.

FIG. 5 is a graph that illustrates the relationship between the percentage of CHF₃ in an etching gas used in Examples of the present invention and the value of E1/E2.

FIG. 6A is a diagram that illustrates an SEM image for explaining evaluation criteria of patterned substrates of an Example of the present invention.

FIG. 6B is a diagram that illustrates an SEM image for explaining evaluation criteria of patterned substrates of an Example of the present invention.

### BEST MODE FOR CARRYING OUT THE INVENTION

Hereinafter, embodiments of the present invention will be described with reference to the attached drawings. However, the present invention is not limited to the embodiments to be described below. Note that in the drawings, the dimensions of the constitutive elements are drawn differently from the actual dimensions thereof, in order to facilitate visual recognition thereof.

### [Resist Pattern Forming Method]

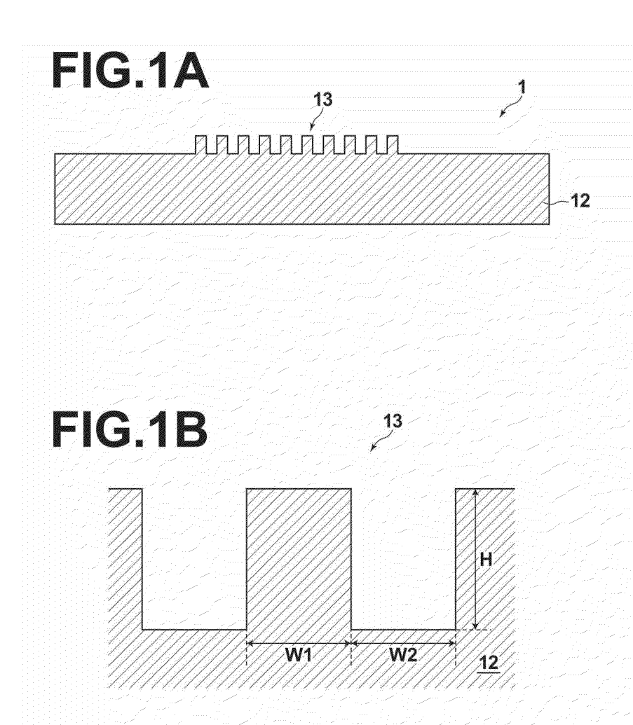

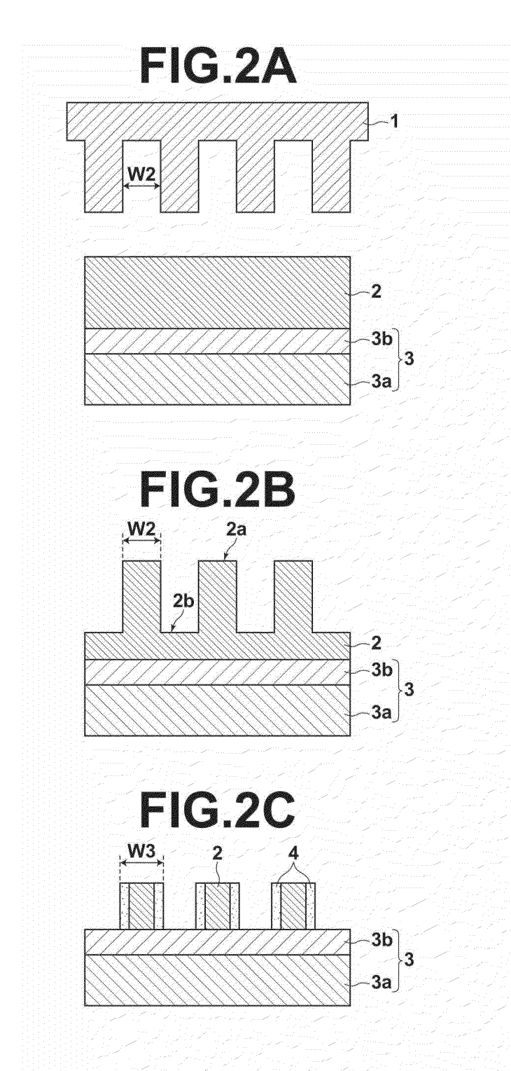

First, an embodiment of a resist pattern forming method will be described. FIG. 1A is a schematic sectional view that illustrates a mold employed in a resist pattern forming method according to an embodiment of the present invention. FIG. 13 is a schematic magnified view that illustrates the cross section of a portion of a patterned region of the mold of FIG. 1A. FIG. 2A through FIG. 2C are schematic sectional views that illustrate the steps of the resist pattern forming method according to the embodiment of the present invention.

The resist pattern forming method of the present embodiment presses a mold 1 having a fine pattern 13 of protrusions and recesses on the surface thereof against a resist film 2 formed on a substrate 3 (FIG. 2A). Next, the mold 1 is separated from the resist film 2, to transfer the pattern 13 of protrusions and recesses onto the resist film 2 (FIG. 2B). Then, residual film etching steps for removing residual film 2b of the resist film 2, onto which the pattern 13 of protrusions and recesses has been transferred, are executed employing a reactive ion etching method (FIG. 2C). The resist pattern forming method of the present invention is characterized by the residual etching steps including a first etching step that employs a first etching gas that includes a sedimentary gas that generates sediment 4 during etching to etch the resist film 2 under conditions such that the sediment 4 is deposited on the side walls of protrusions 2a of a resist pattern, which is the pattern 13 of protrusions and recesses transferred onto the resist film 2, while the residual film 2b is etched; and a second etching step that etches the resist film 2 such that the widths of the protrusions 2a including the deposited sediment 4 become a desired width greater than or equal to the widths of the protrusions 2a prior to the residual film etching steps.

### (Mold)

The mold 1 is constituted by a support portion 12, and a fine pattern 13 of protrusions and recesses which is formed on the surface of the support portion 12, as illustrated in FIG. 1A and FIG. 1B.

The material of the support portion 12 may be: a metal, such as silicon, nickel, aluminum, chrome, steel, tantalum, and tungsten; oxides, nitrides, and carbides thereof. Specific examples of the material of the support portion 12 include silicon oxide, aluminum oxide, quartz glass, Pyrex™ glass, and soda glass.

The shape of the pattern 13 of protrusions and recesses is not particularly limited, and may be selected as appropriate according to the intended use of the nanoimprinting mold. An example of a typical pattern is a line and space pattern as illustrated in FIG. 1A and FIG. 1B. The length of the lines (protrusions), the width W1 of the lines, the distance W2 among the lines, and the height H of the lines from the bottoms of the recesses (the depth of the recesses) are set as appropriate in the line and space pattern. For example, the width W1 of the lines is within a range from 10 nm to 100 nm, more preferably within a range from 20 nm to 70 nm, the distance W2 among the lines is within a range from 10 nm to 500 nm, more preferably within a range from 20 nm to 100 nm, and the height H of the lines is within a range from 10 nm to 500 nm, more preferably within a range from 30 nm to 100 nm. In addition, the shapes of the protrusions that constitute the pattern 13 of protrusions and recesses may be dots having rectangular, circular, or elliptical cross sections.

### (Substrate)

The substrate 3, which is the target of processing, is not limited with regard to the shape, the structure, the size, or the material thereof in the case that the mold 1 has light transmissive properties, and may be selected according to intended use. The surface of the substrate 3 onto which pattern transfer is performed is the resist coating surface. With respect to the shape of the substrate, a substrate having a discoid shape may be utilized in the case that nanoimprinting is performed to produce a data recording medium. With respect to the structure of the substrate, a single layer substrate may be employed, or a laminated substrate may be employed. With respect to the material of the substrate, the material may be selected from among known materials for substrates, such as silicon, nickel, aluminum, glass, and resin. These materials may be utilized singly or in combination. The thickness of the substrate is not particularly limited, and may be selected according to intended use. However, it is preferable for the thickness of the substrate to be 0.05 mm or greater, and more preferably 0.1 mm or greater. If the thickness of the substrate is less than 0.05 mm, there is a possibility that the substrate will flex during close contact with the mold, resulting in a uniform close contact state not being secured. Meanwhile, in the case that the mold 1 does not have light transmissive properties, a quartz substrate is employed to enable the photocurable resin to be exposed to light in the case that a mold 1, which is not light transmissive, is employed. The quartz substrate is not particularly limited as long as it has light transmissive properties and has a thickness of 0.3 mm or greater, and may be selected as appropriate according to intended use. A quartz substrate having the surface thereof coated with a silane coupling agent may be employed. Alternatively, a quartz laminated body having the surface thereof coated with a silane coupling agent may be employed. It is preferable for the thickness of the quartz substrate to be 0.3 mm or greater. If the thickness of the quartz substrate is less than 0.3 mm, it is likely to become damaged during handling or due to pressure during imprinting.

It is preferable for the substrate 3 to have a mask layer 3b having at least one layer on the resist coating surface thereof. In this case, the substrate 3 is constituted by a supporting substrate 3a and the mask layer 3b. The mask layer 3b functions to prevent etching of structures beneath the residual film 2b, that is, the substrate 3, after the residual film 2b is removed by the residual film etching steps. Thereby, damage to the substrate 3 can be suppressed in cases that a point in time that “the widths of the protrusions of the resist pattern including the sediment become a desired value”, which is the endpoint of the residual etching steps, is after a point in time at which the residual film 2b is completely removed. That is, it becomes possible to continue the residual etching steps while suppressing damage to the substrate 3, even if the residual film 2b is completely removed before the widths W3 of the protrusions 2a of the resist pattern including the sediment 4 become the desired value. The material of the mask layer 3b is selected from among those that increase the etching selection ratio (etching speed of the resist film 2/etching speed of the mask layer 3b). It is preferable for the material of the mask layer 3b to be: a metal, such as Cr, W, Ti, Ni, Ag, Pt, and Au; or a metal oxide, such as CrO₂, WO₂, and TiO₂. Further, it is preferable for the mask layer 3b to have at least one layer that includes chrome and/or chrome oxide.

### (Resist Film)

The resist that constitutes the resist film 2 is not particularly limited. The present embodiment may employ a photocurable resin prepared by adding a photopolymerization initiator (2% by mass) and a fluorine monomer (0.1% by mass to 1% by mass) to a polymerizable compound. An antioxidant agent (approximately 1% by mass) may further be added as necessary. The photocurable resist produced by the above procedures can be cured by ultraviolet light having a wavelength of 360 nm. With respect to resist having poor solubility, it is preferable to add a small amount of acetone or acetic ether to dissolve the resist, and then to remove the solvent.

Examples of the polymerizable compound include: benzyl acrylate (Viscoat #160 by Osaka Organic Chemical Industries, K.K.) ethyl carbitol acrylate (Viscoat #190 by Osaka Organic Chemical Industries, K.K.), polypropylene glycol diacrylate (Aronix M-220 by TOAGOSEI K.K.), and trimethylol propane PO denatured triacrylate (Aronix M-310 by TOAGOSEI K.K.). In addition, a compound A represented by the following chemical formula 1 may also be employed as the polymerizable compound.

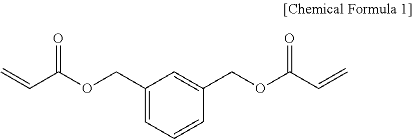 [SMILES: C=CC(=O)OCc1cccc(COC(=O)C=C)c1]

Examples of the polymerization initiating agent include alkyl phenone type photopolymerization initiating agents, such as 2-(dimethylamino)-2-[(4-methylphenyl)methyl]-1-[4-(4-morpholinyl) phenyl]-1-butanone (IRGACURE 379 by Toyotsu Chemiplas K.K.).

In addition, a compound B represented by the following chemical formula 2 may be employed as the fluorine monomer.

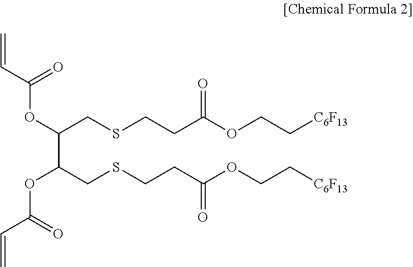

In the case that the photocurable resin is coated by the ink jet method, it is preferable for a photocurable resin formed by mixing the compound represented by Chemical Formula 1, Irgacure 379, and the fluorine monomer represented by Chemical Formula 2 at a ratio of 97:2:1 by mass to be utilized. On the other hand, in the case that the photocurable resin is coated by the spin coat method, it is preferable for a polymerizable compound diluted to 1% by mass with PGMEA (Propylene Glycol Methyl Ether Acetate) to be utilized as the photocurable resin.

### (Mold Pressing Step)

The amount of residual gas is reduced by pressing the mold 1 against the substrate 3 after depressurizing the atmosphere between the mold 1 and the substrate 3, or by causing the atmosphere between the mold 1 and the substrate 3 to be a vacuum. However, there is a possibility that the photocuring resin will volatilize before curing in a vacuum environment, causing difficulties in maintaining a uniform film thickness. Therefore, it is preferable to reduce the amount of residual gas by substituting the atmosphere between the substrate 3 and the mold 1 with a He atmosphere or a depressurized He atmosphere. He passes through the quartz substrate, and therefore the amount of residual gas (He) will gradually decrease. As the passage of He through the quartz substrate takes time, it is more preferable for the depressurized He atmosphere to be employed.

The mold 1 is pressed against the substrate 3 at a pressure within a range from 100 kPa to 10 MPa. The flow of the resin is promoted, the residual gas is compressed, the residual gas dissolves into the photocuring resin, and the passage of He through the quartz substrate is promoted at greater pressures, resulting in improved production efficiency. However, if the pressure is excessive, there is a possibility that the mold and the substrate will be damaged if a foreign object is interposed between the mold 1 and the substrate 3 when the mold 1 contacts the substrate 3. Accordingly, it is preferable for the pressure to be within a range from 100 kPa to 10 MPa, more preferably within a range from 100 kPa to 5 MPa, and most preferably within a range from 100 kPa to 1 MPa. The reason why the lower limit of the pressure is set to 100 kPa is that in the case that the space between the mold and the substrate is filled with liquid when performing imprinting within the atmosphere, the space between the mold and the substrate is pressurized by atmospheric pressure (approximately 101 kPa).

### (Mold Release Step)

After the mold 1 is pressed against the substrate 3 and a pattern of protrusions and recesses is formed on the resist film 2, the mold 1 is separated from the resist film 2. As an example of a separating method, the outer edge portion of one of the mold 1 and the substrate 3 may be held, while the rear surface of the other of the mold 1 and the substrate 3 is held by vacuum suction, and the held portion of the outer edge or the held portion of the rear surface may be relatively moved in a direction opposite the pressing direction. When this step is performed, the widths of the protrusions in the pattern on the curable resin are the same as the intervals W2 between adjacent protrusions in the fine pattern 13 of protrusions and recesses of the mold 1.

### (Residual Film Etching Steps)

The residual film etching steps are steps for removing the residual film 2b at the bottoms of the recesses of the resist pattern. In the present embodiment, the residual film etching steps include the first etching step and the second etching step. RIE (Reactive Ion Etching) suppresses undercutting (side etching). Therefore, an etching process having high vertical anisotropy (movement of ions being biased in the depth direction of the recesses) is preferable. It is preferable for the RIE method to be CCP (Capacitive Coupled Plasma) RIE, helicon wave RIE, ICP (Inductive Coupled Plasma) RIE, or ECR (Electron Cyclotron Resonance) RIE. Further, it is preferable for the present invention to adopt a configuration in which bias power (power to form a bias between plasma and a lower electrode) and plasma power (power to form plasma) are independently controllable, in order to facilitate control of the bias power.

### (First Etching Step)

The first etching step employs a sedimentary gas that generates sediment during etching and etches the resist film 2 under conditions such that the sediment 4 is deposited on the side walls of the protrusions 2a of the resist pattern, which is the pattern 13 of protrusions and recesses transferred onto the resist film 2, while the residual film 2b is etched. In the present specification, the expression “sediment is deposited . . . while the residual film is etched” refers to cases in which deposition of the sediment 4 and etching of the residual film 2b are progressing simultaneously, and also to cases in which the residual film 2b is completely removed and only deposition of the sediment 2b continues to process. In the case that a plurality of etching steps are required to completely remove the residual film 2b, such etching steps as a whole correspond to a single “first etching step”.

The sedimentary gas is a gas that generates sediment, such as reaction products and reaction by products, during etching. It is preferable for the sedimentary gas to be a fluorocarbon gas that generates sediment easily. It is more preferable for the sedimentary gas to be a fluorocarbon gas represented by CHₓF₄₋ₓ. It is most preferable for the sedimentary gas to be at least one of CF₄, CHF₃, and CH₂F₂. In the case that RIE is executed employing the sedimentary gas, the sediment generated by the sedimentary gas is deposited on the side walls of the protrusions 2a of the resist pattern. The sediment 4 which is deposited on the side walls function to protect the side walls from etching. Thereby, so called side etching is suppressed, and as a result, discontinuities are suppressed from being generated in the protrusions 2a of the resist pattern. Particularly in the case that the sedimentary gas is a fluorocarbon gas represented by CHₓF₄₋ₓ, the degree of deposition of the sediment 4 can be adjusted by controlling the percentage of the sedimentary gas within the etching gas, the flow rate of the etching gas, the plasma power, the bias power, the pressure, etc. That is, it is possible to set the widths W3 of the protrusions 2a including the sediment 4 to be a desired value less than or greater than the widths W2 of the protrusions prior to the residual film etching steps, by adjusting the degree of deposition of the sediment 4. Here, the widths of the protrusions 2a of the resist pattern are the full width at half maximum of the protrusions. For example, if the percentage of the sedimentary gas within the etching gas is increased, the degree of deposition of the sediment 4 becomes greater, and therefore the widths W3 of the protrusions 2a including the sediment 4 will become wider. Conversely, if the percentage of the sedimentary gas within the etching gas is decreased, the degree of deposition of the sediment 4 becomes smaller, and therefore the widths W3 of the protrusions 2a including the sediment 4 will become narrower.

It is preferable for the first etching gas to include oxygen gas and/or a noble gas (an inert gas) in addition to the sedimentary gas. Argon gas is particularly preferable as the noble gas. Thereby the control properties with respect to etching rates are improved.

In the first etching step, etching is performed under conditions such that the sediment 4 is deposited on the side walls of the protrusions 2a of the resist pattern, while the residual film 2b is etched. Thereby, it becomes possible to etch the residual film 2b while protecting the resist portions of the protrusions 2a and compensating for etched portions thereof with the sediment 4. The percentage of the sedimentary gas within the etching gas, the flow rate of the etching gas, the plasma power, the bias power, the pressure, etc. are controlled in order to realize such conditions. For example, the aforementioned etching conditions can be realized by setting the percentage of the sedimentary gas in the etching gas to be within a range from 5% to 50%, the flow rate of the etching gas to be within a range from 50 sccm to 200 sccm, the plasma power to be within a range from 20 W to 100 W, the bias power to be within a range from 10 W to 50 W, and the pressure to be within a range from 0.3 Pa to 3 Pa.

The degree of change in the widths of the protrusions of the resist pattern with respect to the amount that the residual film is etched (including over etching) can be understood by calculating the ratio of an etching rate in the height direction with respect to an etching rate in a width direction.

### (Second Etching Step)

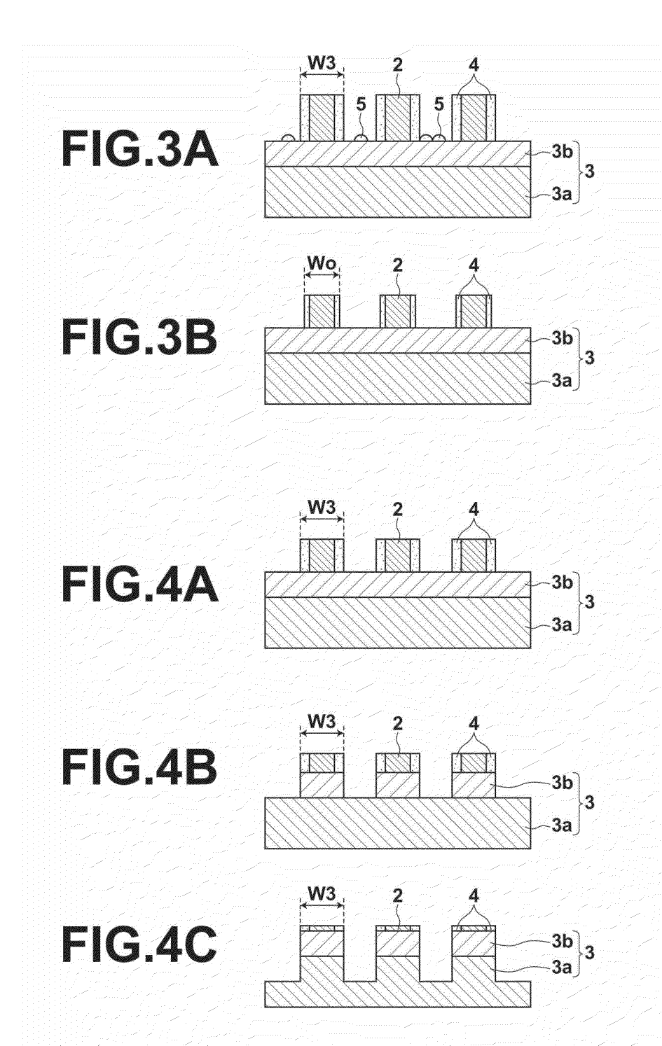

The second etching step is a step for etching unnecessary parts of the sediment 4 which was deposited onto the side walls of the protrusions 2a in the first etching step. FIG. 3A is a schematic sectional view that illustrates the state of a resist pattern following a first etching step and prior to a second etching step in the resist pattern forming method of the present embodiment. FIG. 3B is a schematic sectional view that illustrates the state of the resist pattern following the second etching step in the resist pattern forming method of the present embodiment. In the case that the residual film 2b is completely removed before the widths W3 of the protrusions 2a of the resist pattern including the sediment 4 become a desired value Wo, the first etching step may be ceased at a point in time at which the widths W3 of the protrusions 2a including the sediment 4 become the desired value Wo, to achieve the desired value Wo as the widths W3. However, in the case that the widths W3 become the desired value Wo prior to the residual film 2b being completely removed, it is necessary to continue the first etching step past a point in time at which the widths W3 become the desired value Wo, because the residual film 2b must be completely removed. That is, the widths W3 will be wider than the desired value Wo at the point in time when the residual film 2b is completely removed (or at the point in time when the first etching step is ceased; refer to FIG. 3A). Therefore, a trimming process becomes necessary, to trim the widths W3 to the desired value Wo. Therefore, the second etching step performs etching such that the widths W3 which have become greater than the desired value Wo will become the desire value (FIG. 3B). Note that the second etching step is obviated in cases that the first etching step can achieve the desired value Wo for the widths W3 and completely remove the residual film 2b.

There are also cases in which residue 5 of the sediment remains in the bottoms of the recesses of the resist pattern after the first etching step, as illustrated in FIG. 3A. The second etching step functions to remove such residue 5 as well (FIG. 3B).

As described above, the second etching step functions to trim the protrusions 2a of the resist pattern and to remove the residue 5 of the sediment. It is preferable for etching to be performed in the second etching step with a smaller percentage of the sedimentary gas in the etching gas than the percentage of the sedimentary gas in the etching gas in the first etching step, in order to realize these functions.

As described above, the resist pattern forming method of the present invention is characterized by the residual film etching steps including the first etching step that employs a first etching gas including a sedimentary gas that generates sediment during etching to etch the resist film under conditions such that the sediment is deposited on the side walls of protrusions of a resist pattern, which is the pattern of protrusions and recesses transferred onto the resist film, while the residual film is etched. As a result, it becomes possible for the widths of the protrusions including the deposited sediment to become a desired width greater than or equal to the widths of the protrusions prior to the residual film etching steps. This is considered to be because the sediment being deposited onto the side walls suppresses the resist portions of the protrusions of the resist pattern being etched, and the sediment itself compensates for etched resist portions of the protrusions.

### (Design Modifications to the Resist Pattern Forming Method)

In the first embodiment, the second etching step was the only etching step that functions both to trim the protrusions of the resist pattern and to remove residue of the sediment. However, the present invention is not limited to this configuration. That is, the etching steps having these functions may include a plurality of etching steps, which are executed continuously or discontinuously, having etching conditions different from each other. Here, the expression “executed . . . discontinuously” refers to cases in which long periods of time elapse between etching steps, cases in which etching apparatuses are changed, etc.

A case will be considered in which the total number of etching steps that function both to trim the protrusions of the resist pattern and to remove residue of the sediment is designated as N, and the percentage of sedimentary gas included in the etching gas at an i^{th} (i=1, 2, . . . , N+1) residual film etching step is designated as DGᵢ. That is, the residual film etching step when i=1 corresponds to the first etching step that removes residual film and generates sediment, and the residual film etching steps when i=2 through N+1 correspond to etching steps that function to trim the protrusions and to remove sediment residue. In such a case, it is preferable for etching conditions to be set such that at least one combination in which DGⱼ>DGₖ exists at an arbitrary j^{th} etching step and an arbitrary k^{th} etching step (1≦j<k≦N+1). This is because the residue of the sediment can be more positively removed, by suppressing the generation of sediment in a stepwise manner. Further, it is preferable for the percentages of sedimentary gas included in the etching gas during the residual film etching steps to be set such that they satisfy the following Inequality (1).

DG₁>DG₂> . . . >DG_{N+1} (1)

In addition, if the percentage of oxygen gas included in the etching gas at an i^{th} (i and N are the same as those described above) residual film etching step is designated as OG₁, it is preferable for etching conditions to be set such that at least one combination in which OGₘ>OGₙ exists at an arbitrary m^{th} etching step and an arbitrary n^{th} etching step (1≦m<n≦N+1). Further, it is preferable for the percentages of oxygen gas included in the etching gas during the residual film etching steps to be set such that they satisfy the following Inequality (2).

OG₁<OG₂< . . . <OG_{N+1} (2)

### [Method for Producing Patterned Substrates]

Next, a method for producing patterned substrates according to an embodiment of the present invention will be described. In the present embodiment, a patterned substrate is produced employing the resist pattern forming method described above. FIG. 4A through FIG. 4C are schematic sectional views that illustrate the steps of the method for producing a patterned substrate according to the embodiment of the present invention.

First, the resist pattern forming method described above is employed to form a resist film having a predetermined pattern on a substrate. The pattern of the resist film is formed by the resist pattern forming method of the present invention. Therefore, the widths of the protrusions of the resist pattern are desired widths greater than or equal to the widths of the protrusions prior to the step of etching residual film. Next, the substrate is etched using the patterned resist film as a mask, to form a pattern of protrusions and recesses corresponding to the pattern of protrusions and recesses formed on the resist film, to obtain a patterned substrate having the predetermined pattern.

In the case that a substrate 3 has a laminated structure and includes a mask layer 3b on the surface thereof, the resist pattern forming method described above is employed to form a patterned resist film 2 on the substrate 3 having the mask layer 3b thereon (FIG. 4A). The resist film is formed by the resist pattern forming method of the present invention. Therefore, the widths of the protrusions of the resist pattern are desired widths greater than or equal to the widths of the protrusions prior to the step of etching residual film. Next, dry etching is performed using the resist film 2 as a mask, to form a pattern of protrusions and recesses in the mask layer 3b corresponding to the pattern of protrusions and recesses formed in the resist film 2 (FIG. 4B). Dry etching is further administered onto the substrate 3 using the mask layer 3b as a etching stop layer, to form a pattern of protrusions and recesses in the substrate (FIG. 4C), thereby obtaining a patterned substrate having a predetermined pattern.

The dry etching method is not particularly limited as long as it is capable of forming a pattern of protrusions and recesses in the substrate, and may be selected according to intended use. Examples of dry etching methods include: ion milling; RIE (Reactive Ion Etching); and sputter etching. Among these methods, the ion milling method and RIE (Reactive Ion Etching) are preferred.

The ion milling method is also referred to as ion beam etching. In the ion milling method, an inert gas such as Ar is introduced into an ion source, to generate ions. The generated ions are accelerated through a grid and caused to collide with a sample substrate to perform etching. Examples of ion sources include: Kauffman type ion sources; high frequency ion sources; electron bombardment ion sources; duoplasmatron ion sources; Freeman ion sources; and ECR (Electron Cyclotron Resonance) ion sources.

Ar gas may be employed as a processing gas during ion beam etching. Fluorine series gases or chlorine series gases may be employed as etchants during RIE.

As described above, the method for forming patterned substrates of the present invention is characterized by forming a resist pattern on a resist film by the resist pattern formation method described above, and by etching a substrate using the resist film as a mask, to form a pattern of protrusions and recesses corresponding to the resist pattern on the surface of the substrate. Therefore, etching using a resist pattern having protrusions with widths of a desired value greater than or equal to the widths of the protrusions prior to the residual film etching step as a mask becomes possible. As a result, the accuracy in producing a pattern of protrusions and recesses corresponding to the resist pattern can be improved in the production of patterned substrates.

Examples of the resist pattern forming method of the present invention will be described below.

### Example 1-1

A photocurable resist was coated on a chrome layer (5 nm) provided on a quartz substrate, to form a resist film (60 nm). The components of the photocurable resist were the compound represented by Chemical Formula 1, Irgacure 379, and the fluorine monomer represented by Chemical Formula 2 mixed together at a ratio of 97:2:1 by mass. Thereafter, a Si mold having a pattern of protrusions and recesses, wherein the widths of the protrusions are 20 nm, the heights of the protrusions are 40 nm, and the periodic intervals among the protrusions are 40 nm, was pressed against the resist film, to transfer the pattern of protrusions and recesses on the Si mold to the resist film. At this time, the widths of the protrusions are 20 nm, the heights of the protrusions are 40 nm, and the periodic intervals among the protrusions are 40 nm in a resist pattern formed by the pattern transfer.

The thickness of residual film in the recesses of the resist pattern of the resist film was measured. The thickness of the residual film was measured by exposing the substrate by peeling a portion of a patterned region of the resist film by scratching or tape peeling, then observing the boundary between the peeled region and the patterned region with an AFM (Atomic Force Microscope).

An ICP (Inductive Coupled Plasma) reactive ion etching apparatus was employed to execute the first etching step of the present invention by plasma of etching gas with the etching conditions indicated below. The end point of the execution of the first etching step was a point in time beyond a point in time, at which the residual film was appropriately removed, by 50% of the elapsed time up to that point. That is, the first etching step was executed with a point in time at which an amount of over etching becomes 50% of an average thickness of the residual film as a target. Here, the execution time is calculated based on an etching speed and the thickness of the residual film, which are measured in advance.

### (Etching Conditions)

Etching Gas: CHF₃ gas, oxygen gas, and argon gas, mixed at a ratio of 1:1:10

Plasma Power: 50 W

Bias Power: 25 W

Pressure: 2 Pa

Etching Amount with respect to Average Thickness of Residual Film: 150%

### (Method for Evaluating the Resist Pattern)

An SEM (Scanning Electron Microscope) by Nippon Electron K.

K. capable of measuring lengths was used to evaluate the widths of the protrusions of the resist pattern following the residual film etching step by TOP VIEW observation. In addition, the cross sectional structures were evaluated at the same time. An etching rate E1 in the width direction of the protrusions of the resist pattern (a direction perpendicular to the side walls of the protrusions) was calculated from the widths of the protrusions of the resist pattern (widths including the sediment deposited on the protrusions after the residual film etching step), and an etching rate E2 in the height direction of the protrusions was calculated from the heights of the protrusions after the residual film etching step. Then, a ratio E1/E2 of the etching rate E1 in the width direction with respect to the etching rate E2 in the height direction was calculated.

### Example 1-2

A resist pattern was formed and evaluated in the same manner as in Example 1-1, except that an etching gas in which CHF₃ gas, oxygen gas, and argon gas were mixed at a ratio of 4:1:10 was employed.

### Example 1-3

A resist pattern was formed and evaluated in the same manner as in Example 1-1, except that an etching gas in which CHF₃ gas, oxygen gas, and argon gas were mixed at a ratio of 8:1:10 was employed.

### Example 1-4

A resist pattern was formed and evaluated in the same manner as in Example 1-1, except that an etching gas in which CHF₃ gas, oxygen gas, and argon gas were mixed at a ratio of 12:1:10 was employed.

### Example 1-5

A resist pattern was formed and evaluated in the same manner as in Example 1-1, except that an etching gas in which CHF₃ gas and argon gas were mixed at a ratio of 1:10 was employed.

### Example 1-6

A resist pattern was formed and evaluated in the same manner as in Example 1-1, except that an etching gas in which CHF₃ gas and argon gas were mixed at a ratio of 1:5 was employed.

### Comparative Example 1-1

A resist pattern was formed and evaluated in the same manner as in Example 1-1, except that an etching gas in which oxygen gas and argon gas were mixed at a ratio of 1:10 was employed.

### Comparative Example 1-2

A resist pattern was formed and evaluated in the same manner as in Example 1-1, except that an etching gas in which oxygen gas and argon gas were mixed at a ratio of 1:1 was employed.

### (Results 1)

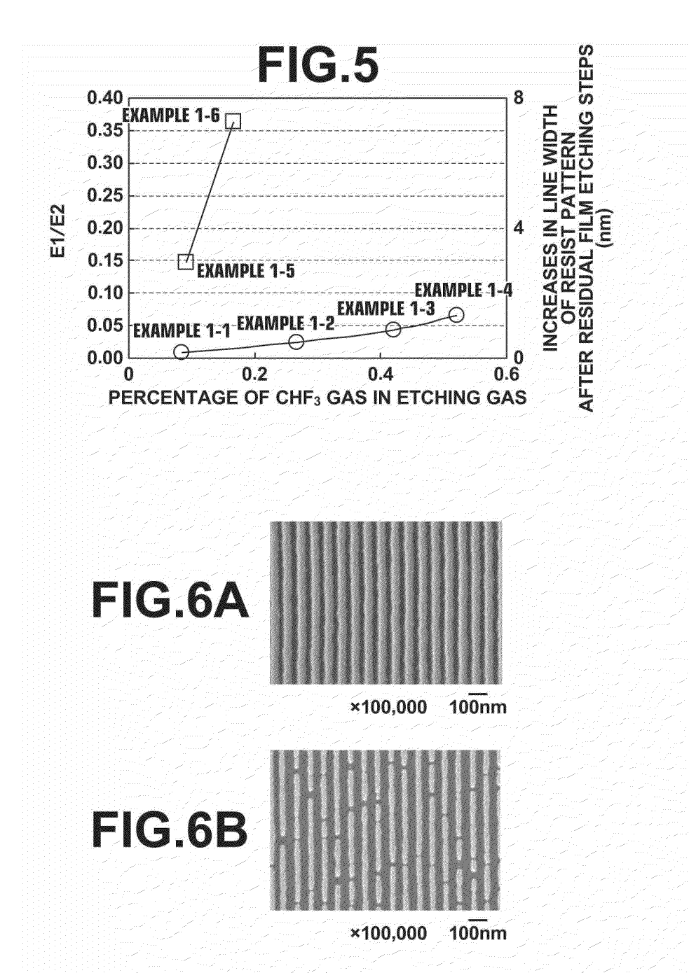

Table 1 below illustrates the evaluation results for Examples 1-1 through 1-6 and Comparative Examples 1-1 and 1-2. FIG. 5 is a graph that illustrates the relationship between the percentage of CHF₃ in the etching gases used in Examples 1-1 through 1-6 and the value of E1/E2. The circular plots in the graph indicate cases in which the etching gas includes oxygen gas, and the square plots in the graph indicate cases in which the etching gas does not include oxygen gas. That the signs for the values of E1/E2 are positive in Table 1 indicate that the widths of the protrusions of the resist pattern after the residual film etching step are wider than the widths of the protrusions of the resist pattern before the residual film etching step. From these results, it was confirmed that the degree of deposition of sediment onto the side walls of the protrusions of the resist patterns can be controlled by controlling the etching conditions. That is, it was confirmed that the widths of the protrusions of the resist pattern following the residual film etching step can be made to be a desired value greater than or equal to the widths of the protrusions of the resist pattern prior to the residual film etching step.

TABLE 1

| | | | | Percentage | |
|---|---|---|---|---|---|
| | Component Ratio of Etching Gas | | | of CHF₃ in | |
| | CHF₃ | Oxygen Gas | Argon Gas | Etching Gas | E1/E2 |
| Example 1-1 | 1 | 1 | 10 | 0.08 | 0.009 |
| Example 1-2 | 4 | 1 | 10 | 0.27 | 0.024 |
| Example 1-3 | 8 | 1 | 10 | 0.42 | 0.043 |
| Example 1-4 | 12 | 1 | 10 | 0.52 | 0.065 |
| Example 1-5 | 1 | 0 | 10 | 0.09 | 0.147 |
| Example 1-6 | 1 | 0 | 5 | 0.17 | 0.383 |
| Comparative | 0 | 1 | 10 | 0.00 | −0.106 |
| Example 1-1 | | | | | |
| Comparative | 0 | 1 | 1 | 0.00 | −0.186 |
| Example 1-2 | | | | | |

### Example 2

### Formation of Resist Pattern

Transfer of a pattern of protrusions and recesses of a Si mold onto a photocurable resist film and measurements of the thickness of residual film were performed in the same manner as in Example 1-1.

An ICP (Inductive Coupled Plasma) reactive ion etching apparatus was employed to execute the first etching step of the present invention with plasma of etching gas using the following etching conditions 1. The end point of the execution of the first etching step was a point in time at which the residual film was appropriately removed. Here, the execution time is calculated based on an etching speed and the thickness of the residual film, which are measured in advance.

Next, an ICP (Inductive Coupled Plasma) reactive ion etching apparatus was employed to execute the second etching step of the present invention with plasma of etching gas using the following etching conditions 2. The end point of the execution of the second etching step was a point in time at which 50% of the residual film can be removed. Here, the execution time is calculated based on an etching speed and the thickness of the residual film, which are measured in advance.

That is, in the present Example, the residual etching steps include the first etching step and the second etching step. An amount of over etching of the first etching step and the second etching step together becomes 50% of an average thickness of the residual film.

### (Etching Conditions 1)

Etching Gas: CHF₃ gas and argon gas, mixed at a ratio of 1:3

Plasma Power: 50 W

Bias Power: 25 W

Pressure: 2 Pa

Etching Amount with respect to Average Thickness of Residual Film: 100%

### (Etching Conditions 2)

Etching Gas: oxygen gas and argon gas, mixed at a ratio of 1:1

Plasma Power: 50 W

Bias Power: 25 W

Pressure: 0.6 Pa

Etching Amount with respect to Average Thickness of Residual Film: 50%

### (Method for Evaluating Increases and Decreases in the Widths of the Protrusions of the Resist Pattern)

An SEM capable of measuring lengths was employed to evaluate increases and decreases in the widths of the protrusions of the resist pattern, by TOP VIEW observation and cross sectional observation. Specifically, whether the widths of the protrusions following the first etching step increased or decreased compared against the widths of the protrusions prior to the first etching step was evaluated.

### (Method for Evaluating Trimming Effects of the Resist Pattern)

An SEM capable of measuring lengths was employed to evaluate the trimming effect of the second etching step, by TOP VIEW observation and cross sectional observation. Specifically, cases in which the widths of the protrusions decreased following completion of the second etching step compared against the widths of the protrusions following completion of the first etching step were evaluated as exhibiting a trimming effect.

### (Method for Evaluating the Presence of Residue)

Whether residue of sediment remained at the bottoms of the recesses of the resist pattern after the residual film etching steps was evaluated. Specifically, the chrome layer was etched by plasma employing a chlorine series gas after the residual etching steps were executed. Then, whether the chrome layer remained was checked by SEM observation. Cases in which the chrome layer remained even partially were evaluated as having residue, and cases in which the chrome layer was no longer present were evaluated as not having residue. Here, the end point of the execution of the chrome layer etching step was a point in time after a point in time, at which the chrome film can be appropriately removed, by 50% of the elapsed time up to that point.

### (Production of Patterned Substrate)

After the residual film etching steps described above were executed, the chrome layer was etched by plasma employing a chlorine series gas. The of the chrome layer etching step was executed to a point in time after a point in time, at which the chrome film can be appropriately removed, by 50% of the elapsed time up to that point. Next, the quartz substrate was etched to a depth of 60 nm by fluorine series gas plasma, to form a pattern of protrusions and recesses corresponding to the resist pattern in the quartz substrate.

### (Method for Evaluating the Patterned Substrate)

An SEM capable of measuring lengths was employed to evaluate the presence of defects in the pattern of protrusions and recesses formed in the patterned substrate. Specifically, whether discontinuities in the protrusions of the pattern of protrusions and recesses and regions at which the pattern of protrusions and recesses could not be formed due to remaining chrome were present was evaluated. FIG. 6A and FIG. 6B are diagrams that illustrate SEM images for explaining evaluation criteria of the patterned substrate of the Example of the present invention. With respect to the presence of discontinuities in the protrusions of the patterned substrate, cases such as that illustrated in FIG. 6A are evaluated as not having discontinuities, and cases such as that illustrated in FIG. 6B are evaluated as having discontinuities. In addition, cases in which residue of sediment was present following the residual film etching steps were evaluated as having regions at which the pattern of protrusions and recesses could not be formed. As a result of the above, cases in which neither defect was present were evaluated as “No Defects” (“Good” in Table 2), and cases in which at least one of the two types of defects were present were evaluated as “Defective” (“Poor” in Table 2).

### Comparative Example 2-1

A resist pattern was formed and evaluated, and a patterned substrate was produced and evaluated in the same manner as that of Example 2, except that the second etching step was not executed, and the amount of etching in the first etching step with respect to an average thickness of the residual film was 150%.

### Comparative Example 2-2

A resist pattern was formed and evaluated, and a patterned substrate was produced and evaluated in the same manner as that of Example 2, except that the first etching step was not executed, and the amount of etching in the second etching step with respect to an average thickness of the residual film was 150%.

### (Results 2)

Table 2 below illustrates the evaluation results for Example 2 and Comparative Examples 2-1 and 2-2. From these results, it was confirmed that according to the resist pattern forming method of the present invention that includes the second etching step, residue of sediment can be removed even in the case that residue is generated in the first etching step. In addition, it was confirmed that the widths of the protrusions of the resist pattern following the residual film etching step can be made to be a desired value greater than or equal to the widths of the protrusions of the resist pattern prior to the residual film etching step.

Further, it was confirmed that the method for forming patterned substrates of the present invention can favorably form patterns of protrusions and recesses on patterned substrates, and that the processing accuracy of patterns of protrusions and recesses are improved.

TABLE 2

| | Component | | Component | | | | | Pattern of |
|---|---|---|---|---|---|---|---|---|
| | Ratio of | | Ratio of | | | | | Protrusions |
| | Etching | | Etching | | | | | and |
| | Gas in | | Gas in | | Resist Pattern after Residual | | | Recesses in |
| | First | | Second | | Film Etching Steps | | | Quartz |
| | Etching | | Etching | | +/− of | | Presence | Substrate |
| | Step | | Step | | Protrusion | Trimming | of | Evaluation |
| | CHF₃ | Ar | O₂ | Ar | Widths | Effect | Residue | Result |
| Example 2 | 1 | 3 | 1 | 1 | Increase | Yes | No | Good |
| Comparative | 1 | 3 | n/a | n/a | Increase | n/a | Yes | Poor |
| Example 2-1 | | | | | | | | |
| Comparative | n/a | n/a | 1 | 1 | Decrease | n/a | No | Poor |
| Example 2-2 | | | | | | | | |

What is claimed is:

1. A resist pattern forming method, comprising:
pressing a fine pattern of protrusions and recesses of a mold having the fine pattern of protrusions and recesses on the surface thereof against a resist film on a substrate;
separating the mold from the resist film, and transferring the pattern of protrusions and recesses onto the resist film; and
executing residual film etching steps to etch the resist film to remove residual film of the resist film, onto which the pattern of protrusions and recesses has been transferred, by a reactive ion etching method;
the residual film etching steps including: a first etching step that employs a first etching gas including a sedimentary gas that generates sediment during etching to etch the resist film under conditions such that the sediment is deposited on the side walls of protrusions of a resist pattern, which is the pattern of protrusions and recesses transferred onto the resist film, while the residual film is etched; and steps following the first etching step that etch the resist film such that the widths of the protrusions including the deposited sediment become a desired width greater than or equal to the widths of the protrusions prior to the residual film etching steps;
the first etching step etching the resist film under conditions that the widths of the protrusions that include the sediment become greater than the desired width; and
the residual film etching step including a second etching step following the first etching step that etches the sediment deposited on the side walls of the protrusions such that the widths of the protrusions including the sediment become the desired width.

2. A resist pattern forming method as defined in claim 1, wherein:
the sedimentary gas is a fluorocarbon gas represented by CHₓF₄₋ₓ, in which x is an integer within a range from 0 to 3.

3. A resist pattern forming method as defined in claim 2, wherein:
the sedimentary gas is at least one of CF₄, CHF₃, and CH₂F₂.

4. A resist pattern forming method as defined in claim 1, wherein:
the percentage of the sedimentary gas in the first etching gas is within a range from 5% to 50%.

5. A resist pattern forming method as defined in claim 1, wherein:
the first etching gas includes oxygen gas.

6. A resist pattern forming method as defined in claim 5, wherein:
the ratio of the oxygen gas with respect to the sedimentary gas within the first etching gas is within a range from 0.01 to 5.

7. A resist pattern forming method as defined in claim 1, wherein:
the first etching gas includes a noble gas.

8. A resist pattern forming method as defined in claim 7, wherein:
the ratio of the noble gas with respect to the sedimentary gas within the first etching gas is within a range from 0.8 to 10.

9. A resist pattern forming method as defined in claim 1, wherein:
the percentage of the sedimentary gas in the first etching gas is greater than the percentage of sedimentary gas in a second etching gas, which is utilized during the second etching step.

10. A resist pattern forming method as defined in claim 1, wherein:
the percentage of oxygen gas in the first etching gas is less than the percentage of oxygen gas in a second etching gas, which is utilized during the second etching step.

11. A resist pattern forming method as defined in claim 1, wherein:
the substrate has at least one mask layer on the surface on which the resist film is formed.

12. A resist pattern forming method as defined in claim 11, wherein:
the at least one mask layer includes at least one layer that includes chrome and/or chrome oxide.

13. A method for producing patterned substrates, comprising:
forming a resist pattern on a resist film by a resist pattern forming method as defined in claim 1; and
etching the substrate using the resist film as a mask, to form a pattern of protrusions and recesses corresponding to the resist pattern on the surface of the substrate.
